(19) United States
(12) Patent Application Publication
(10) Pub. No.: US 2010/0133676 A1
(43) Pub. Date: Jun. 3, 2010

(54) A POWER SEMICONDUCTOR ARRANGEMENT AND A SEMICONDUCTOR VALVE PROVIDED THEREWITH

(75) Inventor: Björn Sandin, Ludvika (SE)

Correspondence Address: VENABLE LLP, P.O. BOX 34385, WASHINGTON, DC, 20043-9998, US

(73) Assignee: ABB TECHNOLOGY LTD., Zürich (CH)

(21) Appl. No.: 12/594,003

(22) PCT Filed: Mar. 30, 2007
(86) PCT No.: PCT/SE2007/050204

§ 371 Date: Sep. 30, 2009

(51) Int. Cl. H01L 25/065; H01L 21/70; H01L 23/52

(52) U.S. Cl. 257/686; 438/109; 438/117; 257/E25.013; 257/E23.141; 257/E21.532

(57) ABSTRACT

A power semiconductor arrangement including a clamping device including a first clamping element and a second clamping element. A plurality of power semiconductor elements are stacked on each other between the first and second clamping elements of the clamping device. The first clamping element receives a clamping force in an axial direction of the stack of the power semiconductor elements. At least one spring element is arranged between the first clamping element and the power semiconductor elements. The at least one spring element presents at least one support surface with which the at least one spring element bears against at least one corresponding support surface of an adjacent element. The at least one spring element includes a helical spring. A center axis of the at least one spring element coincides with a center of the clamping force, or the at least one spring element includes a plurality of helical springs arranged in parallel with each other, which are arranged symmetrically in relation to a point in which a center of the clamping force is introduced into the first clamping element.

### TECHNICAL FIELD

The present invention relates to a power semiconductor arrangement, comprising: at least one power semiconductor element; a clamping device, comprising a first clamping element and a second clamping element, said power semiconductor element being arranged between said first and second clamping elements; and at least one spring element arranged between said first clamping element and said power semiconductor element, wherein said at least one spring element presents at least one support surface with which it bears against at least one corresponding support surface of an adjacent element.

The invention also relates to a semiconductor valve, such as the ones used in thyristors or Insulated Gate Bipolar Transistors (IGBTs) or Integrated Gate Commutated Thyristors (IGCTs), provided with a power semiconductor arrangement according to the invention.

A power semiconductor element is referred to as an element that turn high current on and off at high voltage levels. They are able to flip between these two states in microseconds with very low losses, and have the advantage of being extremely compact. They may be used to transform the shape of an electric current and voltage from alternating current to direct current and vice versa, and from one frequency to another. Accordingly, the invention includes semiconductor elements for such applications.

In particular, the power semiconductor arrangement of the invention is used in medium or high voltage applications, in which the arrangement of the invention is subjected to voltages above approximately 1 kV, and typically a conduction current above 100 A. Typically, but not necessarily, the semiconductor arrangements of the invention present blocking voltages above 1 kV, preferably in the range of 1200 to 8500 V. The maximum conduction current may be p to several thousand amperes.

### BACKGROUND OF THE INVENTION

Power semiconductors are used in semiconductor valves in DC-AC and AC-DC converters, wherein a semiconductor valve comprises a plurality of plate-shaped power semiconductor elements stacked in an interleaving relation with a corresponding plurality of cooling elements in a clamping device. The clamping device serves the function of guaranteeing that there be a controlled and well-defined thermal and electric transfer between the elements of said stack by applying a clamping pressure thereon in an axial direction from one end to another of said stack.

A power semiconductor arrangement like the one just described normally requires a high clamping force in order to present the requested thermal and electric contact.

Power semiconductor suppliers normally require a uniform distribution of the clamping force on the respective power semiconductor element. This is especially important when the entire clamping force is acting on the semiconductor element itself, i.e. when there is no load-adopting structure arranged around the element that adopts all clamping load above a given threshold value.

A uniform pressure distribution is achieved when the clamping force acts in the centre of a contact surface between a power semiconductor element and its adjacent neighbouring power semiconductor element.

Non uniform pressure distribution may occur even when all parts of the power semiconductor arrangement are in their proper places. This may be the case when the clamping device present an excessive torque stiffness. A high clamping torque stiffness makes the clamping sensitive to small deviations in parallelism of the elements present in the arrangement. Any inclination of the direction of the applied clamping force will produce a bending torque that will result in a non-uniform pressure distribution on contact surfaces between the power semiconductor elements and their neighbouring elements.

### PRIOR ART

In order to avoid non-uniform pressure distribution on the power semiconductor elements, clamping devices of prior art comprises one or more spring elements, said spring elements being provided between a clamping element to which a clamping force is applied, and a further clamping element. These two clamping elements are tiltably arranged in relation to each other, in order to let the spring element adopt deviations in parallelism between said clamping elements. These two clamping elements and the spring elements form a unit on one side of a stack of power semiconductor elements, while there is provided yet another clamping element on the opposite side of said stack. As an alternative, the spring elements may be distanced from the clamping elements, for example between separate semiconductor elements in the stack. Moreover, there may be spring elements provided at a plurality of locations along the stack. The spring elements used for this purpose are cup springs, possibly a plurality thereof arranged in series in the clamping force direction.

Another solution of prior art is to provide a ball between the two clamping elements just mentioned, and corresponding recesses as seats for said ball in the opposing surfaces of said elements.

However, at higher clamping forces, the solutions according to prior art seems to be less effective in adopting deviations in parallelism and, thereby, guaranteeing a uniform pressure distribution on contact surfaces between the power semiconductor elements and their neighbouring elements.

### THE OBJECT OF THE INVENTION

It is an object of the present invention to provide a power semiconductor arrangement as initially defined, which remedies the above-mentioned deficiencies of prior art.

The power semiconductor arrangement of the invention should provide for a uniform pressure distribution on contact surfaces between the power semiconductor element or elements and its or their neighbouring elements, also upon application of relatively high pressure forces, such as in the range of 10 kN to 1000 kN.

### SUMMARY OF THE INVENTION

The object of the invention is achieved by the initially defined power semiconductor arrangement, characterised in that said at least one support surface of said at least one spring element is laterally stationary arranged in relation to said at least one corresponding support surface upon compression motion of said spring element. Accordingly, there will be no lateral sliding motion between the at least one spring element and any of its neighbouring elements against which it bears. As a result thereof, friction forces that would counteract a correct adoption of non-parallelism by means of the spring element(s) are avoided, and a more uniform pressure distribution than otherwise is achieved. This is an essential difference to prior art as mentioned earlier, which, for the adoption of non-parallelism, relies on movements between individual parts (ball and ball-seat, spring element and adjacent surface) that are of sliding, and therefore friction-loss inducing, character. The technical effect of the invention will increase along with increasing clamping forces. It should be noted that said compression motion of the spring element includes uneven compression of the spring element, by which one side of the spring element becomes more compressed than another side thereof.

According to one embodiment, said at least one spring element is arranged between said first clamping element and said power semiconductor element, and where the adjacent element is said first clamping element.

According to one embodiment, the power semiconductor arrangement comprises a third clamping element, which is arranged between said spring element and said at least one power semiconductor element, wherein the adjacent element of said spring element is said third clamping element.

According to one embodiment, said third clamping element is tiltable in relation to said first clamping element through the action of said spring element.

According to one embodiment, said at least one spring element comprises a helical spring. A helical spring has the advantage of being able to adopt deviations from parallelism between elements on opposite sides thereof, and upon compression thereof, without any sliding, friction-force inducing motion being necessitated between the contact surfaces of the spring and said further elements.

According to one embodiment, the power semiconductor arrangement comprises a plurality of spring elements arranged in parallel with each other. The arrangement of a plurality of spring elements may be advantageous from a fail-safe point of view, but also adds to a more versatile and effective adoption of deviations from parallelism between elements on opposite thereof.

According to one embodiment, said plurality of spring elements are arranged symmetrically in relation to a point in which a centre of a clamping force is introduced into the first clamping element. Thereby, an even and well-distributed transmission of a clamping force from a first clamping element to the at least one power semiconductor element is provided for.

According to one embodiment, said at least one power semiconductor element is arranged unlimitedly exposed to the pressure of the clamping device, i.e. without any off-loading surrounding structure. Though the invention is applicable to arrangements in which the power semiconductor elements are surrounded, in a radial direction (relative to the axial direction (clamping force direction)) by a load-adopting structure that will adopt all further clamping forces once the power semiconductor element has been compressed to a certain degree, the invention is particularly suitable to applications in which there is no such limiting structure.

According to one embodiment, the power semiconductor arrangement comprises a plurality of power semiconductor elements stapled on each other between said first and second clamping elements of the clamping device.

According to one embodiment, the power semiconductor arrangement comprises at least one cooling element, arranged adjacent to and in electric contact with at least one of said at least one power semiconductor element.

According to one embodiment, the power semiconductor arrangement comprises a plurality of power semiconductor elements and a plurality of cooling elements, each pair of power semiconductor elements being separated by a cooling element in a stack of power semiconductor elements and cooling elements thereby being provided between said first and second clamping elements.

According to one embodiment, said clamping device applies a pressure in the range of 10 kN to 1000 kN onto said at least one power semiconductor element.

The invention also relates to a semiconductor valve, characterised in that it comprises a semiconductor arrangement according to the invention. The semiconductor valve is, in particularly preferred embodiments, a part of a thyristor, an IGBT or an IGCT.

Further features and advantages of the present invention will be disclosed in the following detailed description of the invention.

### BRIEF DESCRIPTION OF THE DRAWINGS

A preferred embodiment of the invention will now be described more in detail, by way of example, with reference to the annexed drawing, on which:

FIG. 1 is a schematic side view of a first embodiment of the invention,

FIG. 2 is a detailed side view of a part of the arrangement of FIG. 1,

FIG. 3 is a side view corresponding to the one of FIG. 2, of a second embodiment of the invention,

FIG. 4 is a cross-section from above of the detail shown in FIG. 2,

FIG. 5 is a side view corresponding to the ones of FIGS. 2 and 3, but of an arrangement according to prior art, and

FIG. 6 is an enlarged representation of a part of the detail of FIG. 5, showing sliding motion between spring element and clamping element.

### DETAILED DESCRIPTION OF THE INVENTION

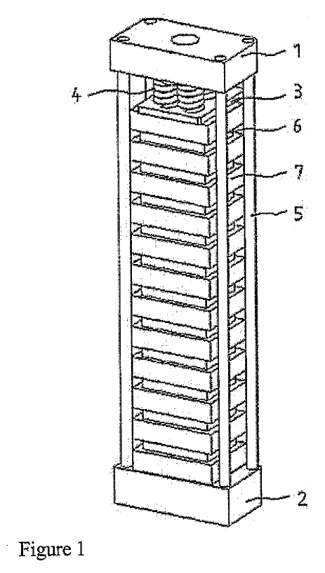

FIG. 1 shows a first embodiment of a power semiconductor arrangement according to the invention. Preferably, the arrangement forms a module in a thyristor, for example a so called IGBT, or transistor in which, typically, high voltage direct current is converted to alternating current or in which high voltage alternating current is converted to direct current.

The arrangement comprises a clamping device that comprises a first clamping element 1, a second clamping element 2, a third clamping element 3, and a plurality of spring elements 4 arranged between the first clamping element 1 and the third clamping element 3. The clamping device also comprises a frame structure, in this case a plurality of elongated members 5 such as rods, that extends between and interconnects the first clamping element 1 to the second clamping element 2.

Between the first clamping element 1 and the third clamping element 2 there is provided a plurality of power semiconductor elements 6 and a corresponding plurality of cooling elements 7. Each semiconductor element 6 is arranged so as to conduct, i.e. open for, a current through it only in one direction and only upon control thereof. In a typical application, in which the inventive arrangement forms a thyristor or transistor module, there are provided control electronics, not shown, for the control of the function of each individual semiconductor element 6. The clamping device has the task of guaranteeing that there be a controlled and well-defined thermal and electric transition over the interfaces between each semiconductor element 6 and its neighbouring element, which in this embodiment is a cooling element 7.

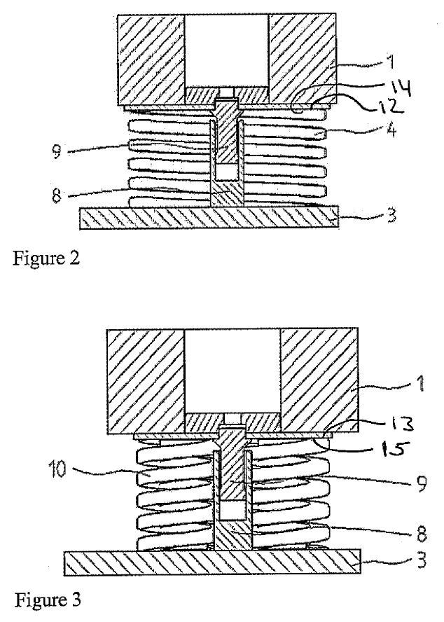

FIG. 2 shows more in detail an embodiment of an upper part of the arrangement of FIG. 1. In the embodiment of FIG. 2, the clamping device comprises a clamping unit comprising the first clamping element 1, the third clamping element 3, and a spring element 4 located between and bearing at opposite ends thereof against the first and third clamping elements 1, 3 respectively. There is also provided a guide arrangement, provided so as to prevent lateral displacement of the first clamping element 1 in relation to the third clamping element, said guide arrangement comprising a cylinder or sleeve-shaped member 8 extending from an upper surface of the third clamping element 3 towards the first clamping element 1, and a piston-shaped or rod-shaped member 9 extending from a lower surface of the first clamping element 1 towards the third clamping element 3 and in sliding engagement with said sleeve-shaped member 8 in an axial direction. However, the guiding arrangement permits a certain tilting of the third clamping element 3 in relation to the first clamping element 1.

The first clamping element 1 is arranged so as to receive a clamping force in an axial direction, i.e. a direction which corresponds to the longitudinal direction of the pile or staple of the power semiconductor elements 6 and cooling elements 7. The clamping force may be produced by means of a hydraulic power device, for example a cylinder-piston arrangement, which is permitted to act on an upper surface of the first clamping element 1.

The first clamping element 1 presents a planar lower surface against which the spring element 4 takes support, and the third clamping element 3 presents a planar upper surface against which the spring element 4 takes support, said upper and lower surfaces being turned towards each other. The spring element 4 of the embodiment of FIG. 2 comprises a single helical spring 4, the centre axis of which coincides with the a centre of the applied clamping force. Accordingly, the clamping force applied to the spring element 4 through the first clamping element 1 should be as evenly distributed as possible, without any torque being applied to the spring element.

In an ideal situation, the upper surface of the third clamping element 3 is supposed to be coplanar and parallel with the opposite lower surface of the first clamping element 1, and the lower surface of the third clamping element be coplanar with the mating surface of its neighbouring element, such as a cooling element 7 or a power semiconductor element 6. Should there, for any reason, still be any deviation from this first coplanar relation, the spring element 4 is arranged so as to adopt this deviation by a purely elastic bending thereof, without any sliding thereof in relation to the surfaces against which it bears. The helical spring 4 is well suited for this purpose. Thanks to the action of the spring element 4, a bending torque, i.e. an uneven application of a clamping force, on the pile of power semiconductor elements 6 and cooling elements 7 is prevented. Thanks to the non-sliding character of the spring element 4, and therefore the absence of any frictional force induced through the clamping force, the functionality of the spring element is provided for even at higher clamping forces. In other words, the adoption of a deviation from the coplanar relation of different parts by the spring element will not be affected by any counteracting frictional force.

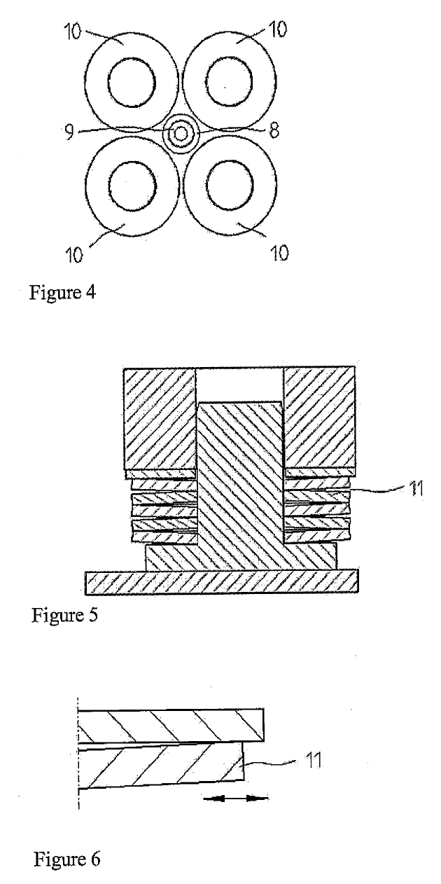

FIGS. 3 and 4 shows an alternative embodiment of the clamping device, in which the unit described above with regard to the first embodiment differs from that embodiment in the sense that it comprises a plurality of spring elements 10. As can be seen in particular in FIG. 4, the spring elements 10 of this embodiment are arranged symmetrically around an assumed centre of a clamping force applied onto the first clamping element 1. In other words, in the case when there is a coplanar relation between the opposing surfaces of the first and third clamping elements 1, 3 against which the spring element 4 bears, and a clamping force is applied in the axial direction, each spring element is to be subjected to the same force and the same degree of compression. Should there be any deviation from said coplanar relation upon application of the clamping force, such deviation will be adopted by the set of spring elements 10 as some of said spring elements 10 will be compressed to a higher degree than others. Also in this case, the spring elements 10 are arranged so as to be compressed, and adopt any deviation from said coplanar relation, without any sliding motion that might induce friction forces that would counteract the functionality of the spring elements in this regard. Each of the spring elements 10 of the embodiment shown in FIGS. 3 and 4 is a helical spring.

FIGS. 5 and 6 show a part of a power semiconductor arrangement of prior art, or more precisely a part corresponding to the one described with reference to FIGS. 2-4. These figures are merely shown to illustrate a main difference between the inventive solution and the one presented by prior art. As can bee seen in FIG. 5, the spring element, indicated with 11, of prior art is an element that, upon compression thereof, will perform a certain sliding motion in relation to an adjacent surface towards which it bears. This is further shown in FIG. 6, which is an enlarged view of a part of a part of FIG. 5. The sliding motion will induce a frictional force, which depends on the size of the applied clamping force and counteracts further compression of the spring element. Accordingly, with increasing clamping force, this counteracting force will become rather important. Given that, upon application of a high clamping force on the unit shown in FIG. 5, the spring element 11 is assumed to adopt a certain deviation from a coplanar relation of opposing surfaces of the clamping elements against which it bears, the induced frictional force will effectively counteract such adoption, and, accordingly, a certain bending torque may be applied to a pile of power semiconductor elements clamped by means of the clamping device. The result thereof will, in the end, be a less effective provision of controlled and well-defined thermal and electrical transition between individual power semiconductor elements 6 than by the solution according to the invention, as described with reference to FIGS. 1-4.

It should be understood that the embodiments of the invention described are only examples of the invention and that alternative solutions within the scope of the invention as limited by the patent claims will be obvious for a person skilled in the art. Accordingly, the scope of protection is defined by the annexed patent claims, supported by the description an the annexed drawing.

1. A power semiconductor arrangement, comprising:
a clamping device, comprising a first clamping element and a second clamping element,
a plurality of power semiconductor elements stacked on each other between said first and second clamping elements of the clamping device, wherein the first clamping element receives a clamping force in an axial direction of the stack of the power semiconductor elements, and
at least one spring element arranged between said first clamping element and said power semiconductor elements, wherein said at least one spring element presents at least one support surface with which the at least one spring element bears against at least one corresponding support surface of an adjacent element, wherein said at least one spring element comprises a helical spring, wherein a center axis of the at least one spring element coincides with a center of the clamping force, or wherein said at least one spring element comprises a plurality of helical springs arranged in parallel with each other, which are arranged symmetrically in relation to a point in which a center of the clamping force is introduced into the first clamping element.

2. The power semiconductor arrangement according to claim 1, wherein said at least one spring element is arranged between said first clamping element and said power semiconductor elements, and wherein an adjacent element is said first clamping element.

3. The power semiconductor arrangement according to claim 1, further comprising:
a third clamping element, which is arranged between said spring element and said at least one power semiconductor element, wherein the an adjacent element of said spring element is said third clamping element.

4. The power semiconductor arrangement according to claim 3, wherein said third clamping element is tiltable in relation to said first clamping element through the action of said spring element.

5. The power semiconductor arrangement according to claim 3, further comprising:
a guide arrangement, comprising
a sleeve-shaped member extending from an upper surface of the third clamping element towards the first clamping element, and
a rod-shaped member extending from a lower surface of the first clamping element towards the third clamping element, wherein the rod-shaped member slidingly engaging said sleeve-shaped member in an axial direction.

6. The power semiconductor arrangement according to claim 1, wherein said power semiconductor elements are arranged unlimitedly exposed to the pressure of the clamping device.

7. The power semiconductor arrangement according to claim 1, further comprising:
at least one cooling element arranged adjacent to and in electric contact with at least one of said power semiconductor elements.

8. The power semiconductor arrangement according to claim 1, further comprising:
a plurality of cooling elements with each pair of power semiconductor elements being separated by a cooling element in the stack of power semiconductor elements.

9. The power semiconductor arrangement according to claim 1, wherein said clamping device applies a pressure in a range of 10 kN to 1000 kN onto said power semiconductor elements.

10. A semiconductor valve, comprising:
a semiconductor arrangement comprising a clamping device, comprising a first clamping element and a second clamping element, a plurality of power semiconductor elements stacked on each other between said first and second clamping elements of the clamping device, wherein the first clamping element receives a clamping force in an axial direction of the stack of the power semiconductor elements, and at least one spring element arranged between said first clamping element and said power semiconductor elements, wherein said at least one spring element presents at least one support surface with which the at least one spring element bears against at least one corresponding support surface of an adjacent element, wherein said at least one spring element comprises a helical spring, wherein a center axis of the at least one spring element coincides with a center of the clamping force, or wherein said at least one spring element comprises a plurality of helical springs arranged in parallel with each other, which are arranged symmetrically in relation to a point in which a center of the clamping force is introduced into the first clamping element.

11. A method for forming a power semiconductor arrangement, the method comprising:
stacking a plurality of power semiconductor elements on each other;
arranging a first clamping element on a first end of the stack of power semiconductor elements;
arranging a second clamping element on a second end of the stack of power semiconductor elements, wherein the clamping elements apply a clamping force in an axial direction of the stack of the power semiconductor elements; and
arranging at least one spring element between the first clamping element and the power semiconductor elements, wherein said at least one spring element includes at least one support surface with which the at least one spring element bears against at least one corresponding support surface of an adjacent element, wherein said at least one spring element comprises a helical spring, wherein a center axis of the at least one spring element coincides with a center of the clamping force, or wherein said at least one spring element comprises a plurality of helical springs arranged in parallel with each other, which are arranged symmetrically in relation to a point in which a center of the clamping force is introduced into the first clamping element.
